(19) United States
(12) Patent Application Publication
(10) Pub. No.: US 2026/0243875 A1
(43) Pub. Date: Aug. 20, 2026

(54) SENSOR AND DETECTION METHOD

(71) Applicant: OMRON Corporation, Kyoto-shi, Kyoto (JP)

(72) Inventors: Shintaro Ando, Kyoto-shi, Kyoto (JP); Norihiro Tomago, Kyoto-shi, Kyoto (JP)

(21) Appl. No.: 19/161,606

(22) PCT Filed: Feb. 21, 2024
(86) PCT No.: PCT/JP2024/006294

§ 371 Date: Sep. 2, 2025

(30) Foreign Application Priority Data
Mar. 15, 2023 (JP) 2023-040356

(51) Int. Cl. G01S 7/487; G01S 7/4865; G01S 17/10

(52) U.S. Cl. CPC G01S 7/487; G01S 7/4865; G01S 17/10

(57) ABSTRACT

A sensor and a detection method that easily suppress a malfunction due to mutual interference. A sensor includes a calculation unit configured to calculate a scramble value by a hash function, based on a value of a periodic pseudorandom number sequence and a unique value of the sensor, a setting unit configured to set a variable signal period based on the scramble value, a transmitting and receiving unit configured to transmit a detection signal DS1 to a target WK and receive a detection signal DS2 reflected by the target WK, based on the signal period, and a detection unit configured to detect the target WK based on a plurality of the received detection signals DS2.

This application is a U.S. national stage application under 35 U.S.C. § 371 of International Application No. PCT/JP2024/006294, filed on Feb. 21, 2024, which claims the benefit of and priority to Japanese Patent Application 2023-040356, filed on Mar. 15, 2023, the entire contents of which are incorporated herein by reference.

### TECHNICAL FIELD

The present disclosure relates to a sensor and a detection method.

### BACKGROUND ART

Patent Document JP 2018-152819 A discloses a photoelectric sensor including, a light projecting unit, configured to repetitively emit a set of pulse light following a projected light pattern in which a light projecting period is made different by a fixed time, as signal light, a light receiving element, configured to receive the signal light from the light projecting unit, and a light receiving control unit, configured to distinguish a light incident state and a light blocked state on the basis of a received light signal from the light receiving element. In the photoelectric sensor, the light projecting unit has a first pattern in which the light projecting period is increased by a fixed time and a second pattern in which the light projecting period is reduced by a fixed time as the projected light pattern, and in the first pattern and the second pattern, a pulse indicating a shortest period is included in the light projecting period other than the shortest period. This photoelectric sensor makes it possible to prevent a malfunction due to mutual interference.

### BRIEF SUMMARY

Here, when a plurality of sensors are arranged for a target, for example, a phenomenon in which light projected from one sensor of two adjacent sensors and reflected by the target is received by the other sensor, so-called mutual interference may occur. The mutual interference may cause an unintended operation, that is, a malfunction of the other sensor.

In sensors of the related art, two sensors each have a plurality of channels each having a light projecting period that is set to a different predetermined time, and different channels are set for the two sensors to prevent a malfunction due to mutual interference. However, this method is troublesome because of requiring channel setting by a user.

The present disclosure has been made in view of the above-described circumstances, and one of objects of the present disclosure is to provide a sensor and a detection method which can easily suppress a malfunction due to mutual interference.

A sensor according to an aspect of the present disclosure is a sensor including a calculation unit configured to calculate a scramble value by a hash function, based on a value of a periodic pseudorandom number sequence and a unique value of the sensor, a setting unit configured to set a variable signal period, based on the scramble value, a transmitting and receiving unit configured to transmit a detection signal to a target and receive the detection signal reflected by the target, based on the signal period, and a detection unit configured to detect the target, based on a plurality of the detection signals received.

According to this aspect, a scramble value is calculated by using the hash function, based on a value of a periodic pseudorandom number sequence and a unique value of the sensor, a variable signal period is set based on the scramble value, a detection signal is transmitted to a target and the detection signal reflected by the target is received, based on the signal period, and the target is detected based on a plurality of the received detection signals. This makes it possible to reduce the risk that, when a plurality of sensors are arranged, the signal periods of adjacent sensors coincide with each other. Therefore, unlike the related art, the user does not need to set different periods for the plurality of sensors, and it is possible to easily suppress a malfunction due to mutual interference. In addition, even when, in adjacent sensors, the signal periods are set using the values of the same pseudorandom number sequence, using the hash function to calculate the scramble value makes it possible to obtain scramble values as a number sequence obtained by changing the order (arrangement) of the periodic pseudorandom number sequence. Therefore, the risk that the signal periods set in the sensors are continuously synchronized with each other can be reduced, and the malfunction due to mutual interference can be further suppressed.

In the above aspect, the setting unit may calculate the signal period, based on a reference period, a spread width, and the scramble value.

According to this aspect, the signal period is calculated based on a reference period, a spread width, and the scramble value. This makes it possible to spread signal periods in a predetermined range.

In the above aspect, a pseudorandom number generation unit configured to generate a value of the pseudorandom number sequence, based on a predetermined seed value may further be included.

According to this aspect, a value of the pseudorandom number sequence is generated based on a predetermined seed value. This makes it possible to easily generate a value of the pseudorandom number sequence which is periodic and reproducible.

In the above aspect, a hash value generation unit configured to generate a hash value, based on the unique value of the sensor may further be included, and the calculation unit may calculate the scramble value, based on the value of the pseudorandom number sequence and the hash value.

According to this aspect, the scramble value calculated by using the hash function is calculated based on the value of the pseudorandom number sequence and the hash value. Accordingly, for example, even when two adjacent sensors have consecutive individual serial numbers, calculating scramble values based on hash values makes it possible to distribute the scramble values in a dispersed manner in a predetermined range.

In the above aspect, the number of digits of the hash value may be equal to the number of digits of the value of the pseudorandom number sequence, and the scramble value may be calculated by using an exclusive OR operation of the value of the pseudorandom number sequence and the hash value.

According to this aspect, when the number of digits of the hash value is equal to the number of digits of the value of the pseudorandom number sequence, the scramble value is calculated by using an exclusive OR operation of the value of the pseudorandom number sequence and the hash value. This makes it possible to change the order (arrangement) of the values in the pseudorandom number sequence and easily calculate the scramble values, when the number of digits of the value of the pseudorandom number sequence is the same as the number of digits of the hash value.

In the above aspect, a cumulative signal generation unit configured to generate a cumulative signal, based on the plurality of received detection signals may further be included, the detection unit may detect the target, based on the cumulative signal.

According to this aspect, the target is detected based on the generated cumulative signal. This makes it possible to average the detection signals received a plurality of times, and thus even if accidental phase coincidence between the signal periods of adjacent sensors occurs, the influence thereof can be weakened by the averaging.

In the above aspect, a signal storage unit configured to store the cumulative signal may further be included, and, in response to reception of the detection signal, the cumulative signal generation unit may add the detection signal to the cumulative signal stored in the storage unit to update the cumulative signal.

According to this aspect, in response to reception of the detection signal, the cumulative signal is updated by adding the detection signal to the cumulative signal stored in the storage unit. Thus, each time a detection signal is received, the detection signal is added to the cumulative signal stored in the storage unit to update the cumulative signal. As a result, by receiving a detection signal a plurality of times, a cumulative signal which is the sum of a plurality of detection signals can be easily generated.

In the above aspect, the transmitting and receiving unit may include a transmitting unit configured to transmit the detection signal to the target, based on the signal period, and a receiving unit configured to receive the detection signal reflected by the target, based on the signal period.

According to this aspect, the transmitting unit for transmitting the detection signal to the target, based on the signal period, and the receiving unit for receiving the detection signal reflected by the target, based on the signal period are included. Accordingly, the transmitting unit and the receiving unit can be implemented (realized) as separate members.

In the above aspect, an input unit configured to receive input of information may further be included.

According to this aspect, an operation unit for inputting information is included. This makes it possible to input externally a spread width and a reference period for setting a signal period, a value of a pseudorandom number sequence, and the like, for example.

In the above aspect, the detection signal may be any one of a light signal, a sound wave signal, and an electromagnetic wave signal.

According to the aspect, the detection signal is any one of a light signal, a sound wave signal, and an electromagnetic wave signal. Accordingly, the transmitting and receiving unit for transmitting and receiving the detection signal can be easily implemented (realized).

A detection method according to another aspect of the present disclosure is a detection method for a sensor, including, calculating a scramble value by a hash function, based on a value of a periodic pseudorandom number sequence and a unique value of the sensor, setting a variable signal period based on the scramble value, transmitting a detection signal to a target and receiving the detection signal reflected by the target, based on the signal period, and detecting the target based on a plurality of the received detection signals.

According to this aspect, a scramble value is calculated by using the hash function, based on a value of a periodic pseudorandom number sequence and a unique value of the sensor, a variable signal period is set based on the scramble value, a detection signal is transmitted to a target and the detection signal reflected by the target is received, based on the signal period, and the target is detected based on a plurality of the received detection signals. This makes it possible to reduce the risk that, when a plurality of sensors are arranged, the signal periods of adjacent sensors coincide with each other. Therefore, unlike the related art, the user does not need to set different periods for the plurality of sensors, and it is possible to easily suppress a malfunction due to mutual interference. In addition, even when, in adjacent sensors, the signal periods are set using the values of the same pseudorandom number sequence, using the hash function to calculate the scramble value makes it possible to obtain scramble values as a number sequence obtained by changing the order (arrangement) of the periodic pseudorandom number sequence. Therefore, the risk that the signal periods set in the sensors are continuously synchronized with each other can be reduced, and the malfunction due to mutual interference can be further suppressed.

According to the present disclosure, it is possible to easily suppress a malfunction due to mutual interference.

### BRIEF DESCRIPTION OF THE DRAWINGS

FIG. 1 is a schematic diagram illustrating an arrangement of a detection system according to one embodiment.

FIG. 2 is a configuration diagram illustrating a configuration of a sensor according to one embodiment.

FIG. 3 is a schematic diagram for explaining generation of a hash value by a hash value generation unit illustrated in FIG. 2.

FIG. 4 is a diagram for explaining calculation of a scramble value by a scramble value calculation unit illustrated in FIG. 2.

FIG. 5 is a diagram for explaining difference between a number sequence obtained by calculating scramble values and a number sequence generated without calculating scramble values.

FIG. 6 is a diagram for explaining difference between signal periods based on scramble values and signal periods which are not based on scramble values.

FIG. 7 is a graph showing difference in simulation results between signal periods based on scramble values and signal periods which are not based on scramble values.

FIG. 8 is a diagram for explaining difference between the case of using a variable signal period and the case of using a fixed signal period.

FIG. 9 is a flowchart for explaining an example of presence detection processing performed by a sensor according to one embodiment.

FIG. 10 is a configuration diagram illustrating a configuration of a sensor according to a first modified example of one embodiment.

FIG. 11 is a configuration diagram illustrating a configuration of a sensor according to a second modified example of one embodiment.

### DETAILED DESCRIPTION

An embodiment of the present disclosure will be described below. In the following description of the drawings, the same or similar parts are denoted by the same or similar reference signs. Note that the drawings are schematic drawings. Thus, specific dimensions and the like should be determined in light of the following description. It goes without saying that different drawings also include parts with dimensional relationships and proportions different from one another. In addition, interpretation of the technical scope of the present disclosure should not be limited to the embodiment.

Note that, to clarify the relationship between the drawings and to help understand the positional relationship, orientation, and the like of each component, some of the drawings may include an orthogonal coordinate system with an X axis and a Y axis for convenience. The X axes and the Y axes in drawings correspond to each other.

In the present embodiment, an example of a photosensor that uses light as a medium of a signal and transmits and receives a light signal will be described unless otherwise specified. As described in modified examples described below, the sensor of the present embodiment is not limited to a case of transmitting and receiving a light signal, and may be a sensor that transmits and receives a signal by another medium, for example, a medium such as a sound wave including an ultrasonic wave or an electromagnetic wave (hereinafter, also referred to as a “radio wave”).

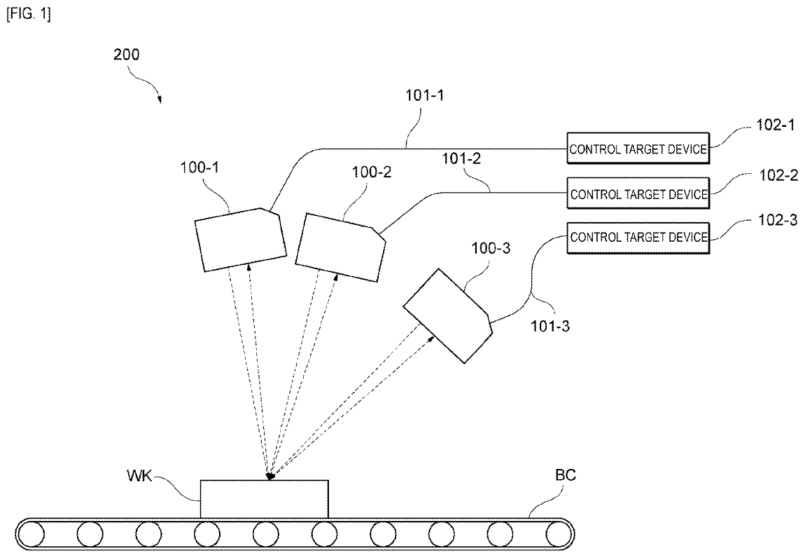

First, a detection system including a photosensor according to one embodiment will be described with reference to FIG. 1. FIG. 1 is a schematic diagram illustrating arrangement of a detection system 200 according to one embodiment.

As illustrated in FIG. 1, the detection system 200 includes a plurality of sensors 100-1, 100-2, 100-3 (hereinafter, these sensors may be collectively referred to as “sensors 100” when distinction between the sensors is not required). Each of the sensors 100-1, 100-2, 100-3 is arranged to detect a target (hereinafter also referred to as a “workpiece WK”). Specifically, for example, each of the sensors 100-1, 100-2, 100-3 is arranged to project light from a position above a conveying device BC such as a conveyor belt installed in a manufacturing line of a factory or the like, to the workpiece WK placed on the conveying device BC, and receive reflected light from the workpiece WK. The sensors 100-1, 100-2, 100-3 are connected to different control target devices 102-1, 102-2, 102-3 via respective cables 101-1, 101-2, 101-3 (hereinafter, these cables may be collectively referred to as “cables 101” when distinction between the cables is not required). The control target devices 102-1, 102-2, 102-3 are, for example, solenoid valves, actuators, or the like, and are configured to operate based on signals output from the sensors 100-1, 100-2, 100-3. The sensors 100-1, 100-2, 100-3 do not perform data communication or exchange of signals with other sensors, and are connected to different control target devices 102-1, 102-2, 102-3, respectively. Therefore, the sensors 100-1, 100-2, 100-3 operate asynchronously.

As illustrated in FIG. 1, when the plurality of sensors 100-1, 100-2, 100-3 are arranged for the workpiece WK, for example, a phenomenon in which light projected from one sensor 100-1 of two adjacent sensors 100-1, 100-2 and reflected by the workpiece WK is received by the other sensor 100-2, so-called mutual interference may occur. The mutual interference may cause an unintended operation, that is, a malfunction of the other sensor 100-2.

In sensors of the related art, two sensors each have a plurality of channels each having a light projecting period that is set to a different predetermined time, and different channels are set for the two sensors, in advance or ex post facto, to prevent a malfunction due to mutual interference.

However, this method is troublesome because of requiring channel setting by a user.

### Configuration

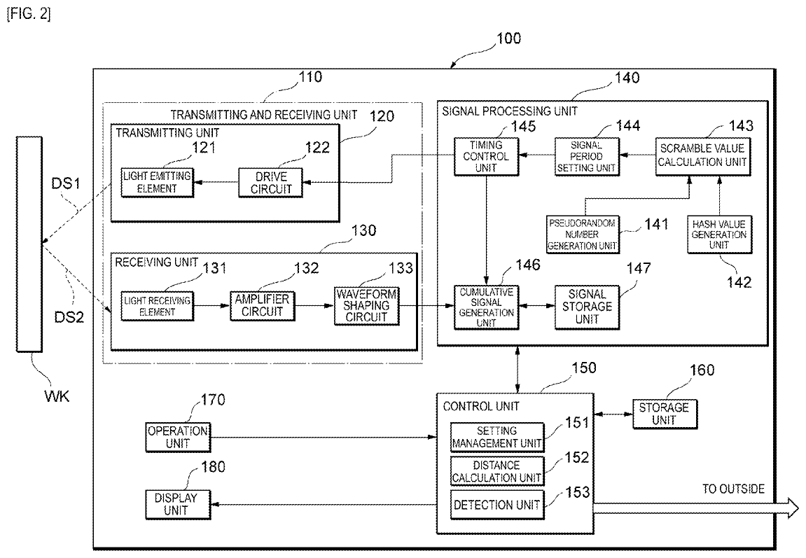

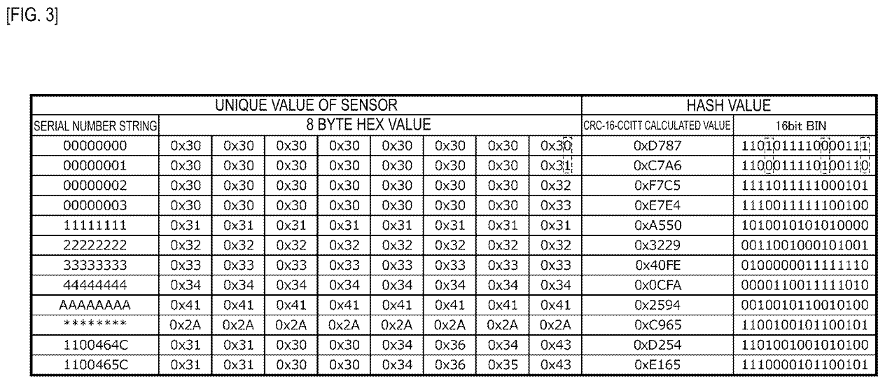

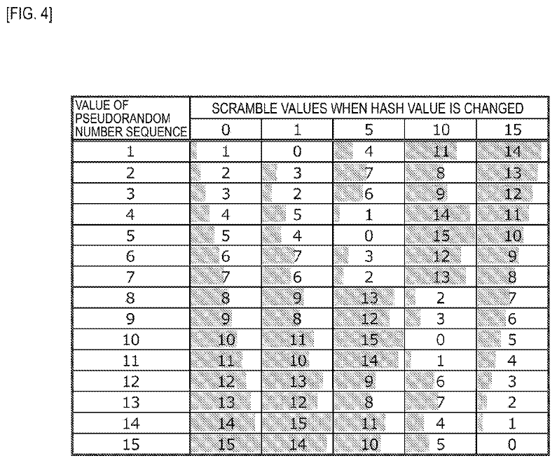

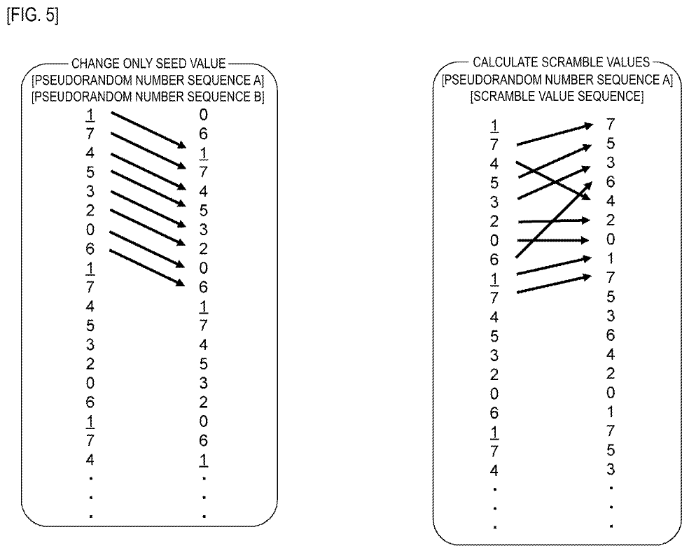

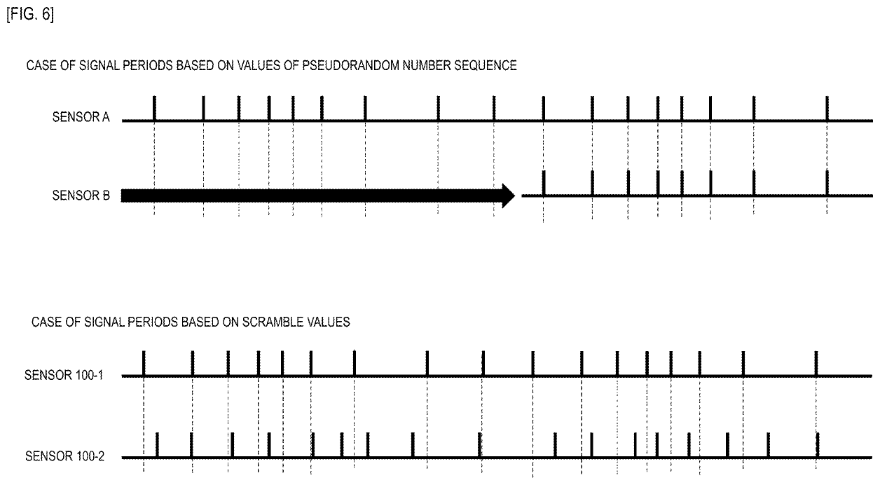

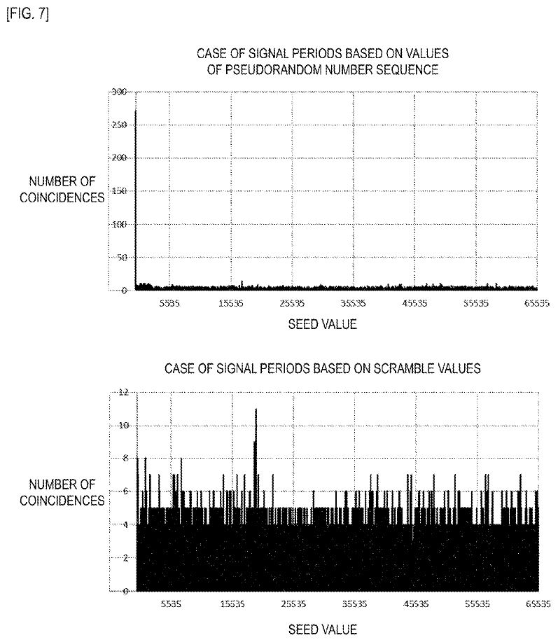

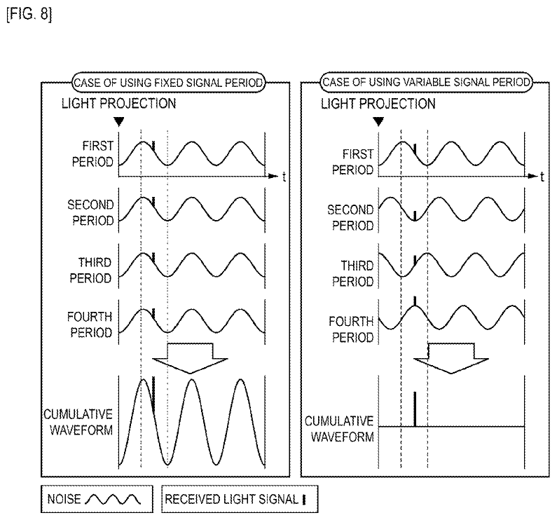

Next, a configuration of a sensor according to one embodiment will be described with reference to FIGS. 2 to 8. FIG. 2 is a configuration diagram illustrating a configuration of the sensor 100 according to one embodiment. FIG. 3 is a schematic diagram for explaining generation of a hash value by a hash value generation unit 142 illustrated in FIG. 2. FIG. 4 is a diagram for explaining calculation of a scramble value by a scramble value calculation unit 143 illustrated in FIG. 2. FIG. 5 is a diagram for explaining difference between a number sequence obtained by calculating scramble values and a number sequence generated without calculating scramble values. FIG. 6 is a diagram for explaining difference between signal periods based on scramble values and signal periods which are not based on scramble values. FIG. 7 is a graph showing difference in simulation results between signal periods based on scramble values and signal periods which are not based on scramble values. FIG. 8 is a diagram for explaining difference between the case of using a variable signal period and the case of using a fixed signal period.

The sensor 100 in the present embodiment is a sensor that detects the presence or absence of the workpiece WK, the distance from the sensor 100 to the workpiece WK, and the like. The sensor 100 is configured to project light toward the workpiece WK and receive light reflected back from the workpiece WK.

In the following description, unless otherwise indicated, an example is described in which the sensor 100 is a Time of Flight (TOF) sensor that detects distance by measuring the round trip time of light projected to and reflected by the workpiece WK. The sensor of the present embodiment is not limited to the TOF sensor, and may be another photosensor, for example, a photoelectric sensor using triangulation as a measurement principle.

As illustrated in FIG. 2, the sensor 100 includes, for example, a transmitting and receiving unit 110, a signal processing unit 140, a control unit 150, a storage unit 160, an operation unit 170, and a display unit 180.

The transmitting and receiving unit 110 is configured to transmit a detection signal DS1 to the workpiece WK and receive a detection signal DS2 reflected by the workpiece WK, based on a signal period. The signal period is variable and is set by a signal period setting unit 144 described below.

As illustrated in FIG. 2, the transmitting and receiving unit 110 may include a transmitting unit 120 and a receiving unit 130.

The transmitting unit 120 is configured to transmit the detection signal DS1 to the workpiece WK based on the signal period. The transmitting unit 120 includes, for example, a light emitting element 121 and a drive circuit 122. The light emitting element 121 is, for example, a laser diode that emits red light having a wavelength in a range from 635 nm to 680 nm. Note that the light emitting element 121 is not limited to a laser diode that emits coherent light and may be an element that emits incoherent light, such as a light emitting diode (LED). The drive circuit 122 generates a drive signal for driving the light emitting element 121 based on a signal input from a timing control unit 145 of the signal processing unit 140 described below, and outputs the drive signal to the light emitting element 121. Therefore, the drive signal of the drive circuit 122 serves as a trigger for the detection signal DS1 transmitted from the light emitting element 121. Based on the drive signal, the light emitting element 121 emits the detection signal DS1 which is a light pulse modulated to a specific frequency in a range, for example, from about 250 kHz to about 600 kHz. Setting the waveband of the detection signal DS1 within the visible band allows a spot emitted onto the workpiece WK to be visually recognized, and thus is suitable for adjusting the detection signal DS1 to be emitted in a desired direction or checking the irradiated portion on the target WK.

The receiving unit 130 is configured to receive the detection signal DS2 reflected by the workpiece WK based on the signal period described above. The receiving unit 130 includes, for example, a light receiving element 131, an amplifier circuit 132, and a waveform shaping circuit 133. The light receiving element 131 is, for example, a photodiode such as an Avalanche Photo Diode (APD) or Single Photon Avalanche Diode (SPAD), or a CMOS sensor having a two dimensional array of photoelectric conversion pixels. The light receiving element 131 receives the detection signal DS2, which is a light signal, and converts the detection signal DS2 into an electrical signal. The detection signal converted into the electric signal is amplified by the amplifier circuit 132 with a predetermined gain, and the signal waveform of the detection signal is shaped by the waveform shaping circuit 133. The shaped detection signal is output to the signal processing unit 140. Note that FIG. 2 illustrates a case where the path of the detection signal DS1 transmitted toward the workpiece WK and the path of the detection signal DS2 reflected by the workpiece WK are different. When the paths of detection signal DS1 and the detection signal DS2 are the same, the detection signal DS1 and the detection signal DS2 are separated using, for example, a half mirror.

As described above, the transmitting and receiving unit 110 includes the transmitting unit 120 that transmits the detection signal DS1 to the workpiece WK based on the signal period and the receiving unit 130 that receives the detection signal DS2 reflected by the workpiece WK based on the signal period, and thus the transmitting unit 120 and the receiving unit 130 can be implemented (realized) as separate members.

Although, in the present embodiment, an example in which the sensor 100 includes the transmitting unit 120 and the receiving unit 130 as separate members is described, the sensor 100 is not limited thereto. The sensor 100 may include an integrated member including a part or the whole of the transmitting unit 120 and a part or the whole of the receiving unit 130.

The signal processing unit 140 is configured to perform processing on the detection signal DS1 transmitted from the transmitting unit 120 and the detection signal DS2 received by the receiving unit 130. In particular, the signal processing unit 140 is configured to execute various processes related to the signal period of the detection signal DS1 and the detection signal DS2. The signal processing unit 140 includes, for example, an integrated circuit, such as a field programmable gate array (FPGA) or the like. The integrated circuit may include a storage device such as a cache memory mounted on a chip or in a package. Note that the integrated circuit of the signal processing unit 140 are not limited to FPGAs, and the integrated circuit such as a Central Processing Unit (CPU), Digital Signal Processor (DSP), Application Specific Integrated Circuit (ASIC), Programmable Logic Device (PLD), or System-on-a-Chip (SoC) may be used. Details of the signal processing unit 140 will be described below.

The signal processing unit 140 is configured to exchange data and signals with the control unit 150 described below. For example, the signal processing unit 140 and the control unit 150 are connected to each other by one or more buses and signal lines, and transmission and reception of data and input and output of signals can be performed bidirectionally.

The control unit 150 is configured to control operation of each unit of the sensor 100. In particular, the control unit 150 is configured to execute various processes related to detection of the workpiece WK. The control unit 150 includes, for example, an integrated circuit such as a CPU. The integrated circuit may include a storage device such as a cache memory mounted on a chip or in a package. Note that the integrated circuit of the control unit 150 is not limited to CPU, and may be an integrated circuit such as a DSP, an ASIC, a PLD, an FPGA, or a SoC. Details of the control unit 150 will be described below.

Although, in the present embodiment, an example in which the sensor 100 includes the signal processing unit 140 and the control unit 150 as separate members is described, the sensor 100 is not limited thereto. The sensor 100 may include an integrated member including a part or the whole of the signal processing unit 140 and a part or the whole of the control unit 150.

The storage unit 160 is for storing a program, data, and the like. The storage unit 160 includes, for example, a memory such as a Read Only Memory (ROM), an Erasable Programmable ROM (EPROM), an Electrically Erasable Programmable ROM (EEPROM), and/or a Random Access Memory (RAM). The storage unit 160 stores information such as a seed value, an individual serial number, a spread width, a reference period, the number of addition operations, and a threshold value, in advance. The number of pieces of each type of information is not limited to one, and may be two or more.

The operation unit 170 is configured to function as an input unit for inputting information. More specifically, the operation unit 170 is configured to generate data corresponding to information input by a user operation. The operation unit 170 includes an operation member for receiving an instruction from a user, for example, an UP button, a DOWN button, or a directional pad. Note that the operation member is not limited to a button and another input device such as a touch sensor or keyboard may be included. The operation unit 170 may also have a function of receiving designation of a spread width and a reference period for setting a signal period in cooperation with a setting management unit 151 of the control unit 150 described below. Further, the operation unit 170 may have a function of receiving an input to various items of the sensor 100.

As described above, the sensor 100 includes the operation unit 170 for inputting information, and thus, for example, a spread width and a reference period for setting a signal period, a value of a pseudorandom number sequence, and the like can be input externally.

The display unit 180 is for displaying a setting state of the sensor 100, distance information as a detection result, detection information, non-detection information, and the like. The display unit 180 includes a display device such as a liquid crystal display, an Electro Luminescence (EL) display, a seven segment display, or a Liquid Crystal Display (LCD). Note that the display unit 180 may include an LED or the like for indicating the setting state of the sensor 100, instead of the display device or together with the display device.

### Functional Configuration of Signal Processing Unit

The signal processing unit 140 may include, as functions, a pseudorandom number generation unit 141, a hash value generation unit 142, a scramble value calculation unit 143, a signal period setting unit 144, a timing control unit 145, and a signal storage unit 147, for example.

The pseudorandom number generation unit 141 is configured to generate a value of a pseudorandom number sequence based on a predetermined seed value. The value generated by the pseudorandom number generation unit 141 is one of periodic pseudorandom number sequences. The predetermined seed value is stored in advance in the storage unit 160, for example, and in the present embodiment, “1” is given unless otherwise specified.

Specifically, the pseudorandom number generation unit 141 uses an n-bit (n is a positive integer equal to or greater than 2) Linear Feedback Shift Register (LFSR) to generate an m-sequence of n-bit pseudorandom numbers. That is, the pseudorandom number sequence generated by the pseudorandom number generation unit 141 has a cycle formed by a sequence of 2ⁿ−1 numerical values (states) that transitions in a predetermined order (arrangement) and returns to the first value (excluding the case of being all zero). The pseudorandom number sequence can be reproduced by setting a seed value, and when the same seed value is given, the same value of the pseudorandom number sequence is generated.

In this way, generating the value of the pseudorandom number sequence based on the predetermined seed value, makes it possible to easily generate a value of a periodic and reproducible pseudorandom number sequence.

In the present embodiment, an example is described in which the number of bits is 16 bits (n=16), and the pseudorandom number generation unit 141 generates 65535 (2¹⁶−1) different values as a value of the pseudorandom number sequence. That is, the value of the pseudorandom number sequence is represented as a 16-bit value.

The hash value generation unit 142 is configured to generate a hash value based on a unique value of the sensor 100. The unique value of the sensor 100 is a value unique to the sensor 100 and is a unique value assigned to that sensor 100. The unique value is, for example, an individual serial number of the sensor 100. In the present embodiment, an example in which the individual serial number is an 8-byte ASCII character string will be described.

Further, a variety of algorithms may be employed for generating a hash value by the hash value generation unit 142. FIG. 3 shows an example in which CRC-16-CCITT, which is one of cyclic redundancy checks (CRC), is selected as an algorithm for generating a hash value from the unique value of the sensor 100. As shown in FIG. 3, the generated hash value has the same number of digits as the above-described value of the pseudorandom number sequence. In other words, the generated hash value is a 16-bit value. For example, even when two sensors 100 have consecutive unique values which are different in only one bit, (e.g., “00000000” and “00000001”), the hash values generated by the hash value generation unit 142 are different in three bits (digits).

Generating a hash value based on the unique value of the sensor 100 in this manner, makes it possible to generate a 16-bit hash value from an 8-byte individual serial number, for example, and thus conversion into a hash value having a desired number of digits can be achieved.

Returning to the description of FIG. 2, the scramble value calculation unit 143 is configured to calculate a scramble value by a hash function based on the value of the pseudorandom number sequence and the unique value of the sensor 100. The value of the pseudorandom number sequence is, for example, a value generated by the pseudorandom number generation unit 141. The unique value of the sensor 100 is, for example, the individual serial number of the sensor 100 itself described above or a value based on the individual serial number.

More specifically, when the sensor 100 includes the hash value generation unit 142, the scramble value calculation unit 143 is configured to calculate a scramble value by the hash function based on the value of the pseudorandom number sequence and the hash value. Accordingly, for example, even when two adjacent sensors have consecutive individual serial numbers, calculating scramble values based on hash values makes it possible to distribute the scramble values in a dispersed manner in a predetermined range.

Various hash functions may be used for the calculation of the scramble value by the scramble value calculation unit 143. FIG. 4 shows an example in which an exclusive OR (XOR) is used as a hash function. In addition, in FIG. 4, for simplification of description, an example is shown in which the values of the pseudorandom number sequence are consecutive values from “1” to “15”. As shown in FIG. 4, when the hash value is changed, except for the case where the hash value is “0”, scramble values obtained by the exclusive OR operation of the values of the pseudorandom number sequence and the hash value are in an order obtained by shuffling the consecutive order (arrangement) of the values of the pseudorandom number sequence.

Here, a difference between a number sequence obtained by calculating scramble values and a number sequence generated without calculating scramble values is described. As illustrated on the right side of FIG. 5, when the scramble value calculation unit 143 calculates the scramble value based on a value of a pseudorandom number sequence A and the unique value of the sensor 100 by, for example, the exclusive OR operation, the sequence of the scramble values can have at least some exchanged positions in the order of values, with respect to the order (arrangement) of the pseudorandom number sequence A.

In contrast, as illustrated on the left side of FIG. 5 for comparison with the sensor 100 of the present embodiment, it is assumed that values of a pseudorandom number sequence B are generated only by using a seed value different from that of the pseudorandom number sequence A. From comparison between the values of the pseudorandom number sequence A and the values of the pseudorandom number sequence B, it can be seen that the values of the pseudorandom number sequence B and the pseudorandom number sequence A have different initial values but still have the same order (arrangement).

When the number of digits of the hash value is equal to the number of digits of the value of the pseudorandom number sequence, the scramble value may be calculated by using the exclusive OR (XOR) operation of the value of the pseudorandom number sequence and the hash value. This makes it possible to change the order (arrangement) of the values in the pseudorandom number sequence and easily calculate the scramble values, when the number of digits of the value of the pseudorandom number sequence is the same as the number of digits of the hash value.

The calculation of the scramble value is not limited to calculation by the exclusive OR (XOR) operation. The scramble value calculation unit 143 may calculate the scramble value using a method other than the exclusive OR, for example, a predetermined hash function. More specifically, the scramble value may be a value output by a hash function that receives, as inputs, a value of the pseudorandom number sequence and a value based on the unique value of the sensor 100. This makes it possible to change the order (arrangement) of the values in the pseudorandom number sequence, and easily obtain the scramble value regardless of the number of digits of the value input to the hash function.

Returning to the description of FIG. 2, the signal period setting unit 144 is configured to set a signal period based on a scramble value. The signal period to be set is variable, that is, a period that can be changed. The signal period setting unit 144 changes and sets the signal period, for example, each time the scramble value is calculated.

More specifically, the signal period setting unit 144 is configured to calculate the signal period based on a reference period, a spread width, and a scramble value. The reference period and the spread width are stored in the storage unit 160, and are set in advance by the setting management unit 151 described below before the workpiece WK is detected.

Specifically, a signal period Tm (m is a positive integer representing a period number) is calculated by, for example, the following Equation (1).

$$Signal period Tm = Reference period + \{ ( Spread width \times Scramble value ) / 32768 \} - Spread width \qquad ( 1 )$$

The signal periods Tm calculated using Equation (1) are distributed in a range from (reference period−spread width) to (reference period+spread width−1). Calculating the signal period Tm based on the reference period, the spread width, and the scramble value in this manner, makes it possible to spread the signal periods Tm in a predetermined range.

Here, difference between signal periods based on scramble values and signal periods which are not based on scramble values is described. As illustrated in the lower part of FIG. 6, in a case where, in two adjacent sensors 100, for example, the sensor 100-1 and the sensor 100-2 illustrated in FIG. 1, scramble values are calculated by using, for example, the exclusive OR operation and the signal period setting unit 144 sets signal periods based on the scramble values, even when the phases of two signal periods coincide with each other in a certain period, the possibility of occurrence of phase coincidence in the next period may be low, because the scramble values are values obtained by changing the order (arrangement) of the pseudorandom number sequence. Note that the example in the lower part of FIG. 6 corresponds to the example illustrated on the right side of FIG. 5.

In contrast, as illustrated in the upper part of FIG. 6 for comparison with the sensor 100 of the present embodiment, in a case where, in two adjacent virtual sensors A and B, a signal period based on a value of the pseudorandom number sequence A and a signal period based on a value of the pseudorandom number sequence B generated only by using a different seed value are set, occurrence of phase coincidence between two signal periods in a certain period may indicate a high possibility of consecutive occurrence of phase coincidence in the subsequent periods. Note that the example in the upper part of FIG. 6 corresponds to the example illustrated on the left side of FIG. 5.

Returning to the description of FIG. 2, the timing control unit 145 generates a timing signal based on the set signal period. The timing signal is, for example, a pulse-shaped signal, and is generated at a timing corresponding to the set signal period. The generated timing signal is output to the transmitting unit 120 and is also output to a cumulative signal generation unit 146.

The cumulative signal generation unit 146 is configured to generate a cumulative signal based on a plurality of received detection signals. The generated cumulative signal is, for example, a signal generated by adding the detection signals received a plurality of times, as many times as the number of times of reception.

As described above, the timing signal is input from the timing control unit 145 to the cumulative signal generation unit 146. The cumulative signal generation unit 146 operates according to the timing signal, and receives, within a predetermined period based on the timing signal, the detection signal output from the receiving unit and input to the cumulative signal generation unit 146. Then, the cumulative signal generation unit 146 generates the cumulative signal based on the detection signals received the plurality of times. As a result, the detection signals received the plurality of times can be averaged.

Here, difference in simulation results between signal periods based on scramble values and signal periods which are not based on scramble values is described. In the simulation shown in FIG. 7, the reference period is 265 clocks in the case of 165 MHz operation, which is about 1.6 [μs] (=265/165 MHz), the spread width is 26 clocks in the case of 165 MHz operation, which is about 0.16 [μs] (=26/165 MHz), the number of addition operations is 270, the hash value of one of the two sensors is fixed to “0x0D787”, the hash value of the other sensor is fixed to “0xC7A6”, and the seed value of the one of the two sensors is fixed to “1”. In the graph, the horizontal axis represents the seed value in the other sensor that is changed from “1” to “65535”, and the vertical axis represents the number of coincidences between the detection signals transmitted by the two sensors.

As illustrated in the lower part of FIG. 7, for example, when a scramble value is calculated by using the exclusive OR operation and the signal period setting unit 144 sets a signal period based on the scramble value, the maximum number of coincidences, that is, phase coincidences between the signal periods of the two sensors is about 11. In general, the allowable number of coincidences is about 1/10 or less of the number of addition operations, and in the simulation result in the lower part, the number of coincidences is 27 or less, and thus it can be considered that a malfunction due to mutual interference is unlikely to occur. Note that the simulation result in the lower part of FIG. 7 corresponds to the example illustrated in the lower part of FIG. 6.

In contrast, as illustrated in the upper part of FIG. 7 for comparison with the sensor 100 of the present embodiment, in a case where, in two sensors, a signal period based on a value of the pseudorandom number sequence A and a signal period based on a value of the pseudorandom number sequence B generated only by using a different seed value are set, the number of coincidences is significantly increased when the seed value is “1”. In this case, it can be said that there is a high risk that at least one of the two sensors malfunctions due to mutual interference. Note that the simulation result in the upper part of FIG. 7 corresponds to the example illustrated in the upper part of FIG. 6.

Returning to the description of FIG. 2, the signal storage unit 147 is configured to store the generated cumulative signal. The cumulative signal generation unit 146 is connected to the signal storage unit 147, and the cumulative signal generation unit 146 can read information from the signal storage unit 147 and write information to the signal storage unit 147. In the signal storage unit 147, in response to reception of a detection signal, the cumulative signal is updated by adding the detection signal to the cumulative signal stored in the signal storage unit 147.

As described above, in response to reception of a detection signal, the cumulative signal is updated by adding the detection signal to the cumulative signal stored in the signal storage unit 147. Thus, each time a detection signal is received, the detection signal is added to the cumulative signal stored in the signal storage unit 147 to update the cumulative signal. As a result, by receiving a detection signal a plurality of times, a cumulative signal which is the sum of a plurality of detection signals can be easily generated.

Note that at least one of the pseudorandom number generation unit 141, the hash value generation unit 142, the scramble value calculation unit 143, the signal period setting unit 144, the timing control unit 145, and the signal storage unit 147 may be implemented by a processor, which is an example of the integrated circuit of the signal processing unit 140, executing a program stored in the storage unit 160. When a program is executed, the program may be stored in a storage medium. The storage medium storing the program may be a non-transitory computer readable medium. The non-transitory storage medium is not particularly limited, but may be a storage medium such as a Universal Serial Bus (USB) flash drive, an embedded Multi Media Card (MMC), a Secure Digital (SD) memory card, or a Solid State Drive (SSD).

The functions of the signal processing unit 140 illustrated in FIG. 2 are examples. The signal processing unit 140 may have another function different from these functions, or may not have one or more of these functions.

### Functional Configuration of Control Unit

The control unit 150 may include, for example, a setting management unit 151, a distance calculation unit 152, and a detection unit 153, as functions.

The setting management unit 151 is for managing settings for the sensor 100. The settings to be managed by the setting management unit 151 include, for example, a reference period, a spread width, the number of addition operations, and the like. More specifically, a reference period, a spread width, and the number of addition operations, which are associated with a response time determined by user operation via the operation unit 170, are set. For example, a reference period of 1.6 [μs], a spread width of 0.2 [μs], and the number of addition operations of 250 [times] are associated with a response time of 2 [ms], a reference period of 4.0 [μs], a spread width of 0.2 [μs], and the number of addition operations of 500 [times] are associated with a response time of 10 [ms], a reference period of 4.0 [μs], a spread width of 0.2 [μs], and the number of addition operations of 2500 [times] are associated with a response time of 50 [ms], and a reference period of 4.0 [μs], a spread width of 0.2 [μs], and the number of addition operations of 10000 [times] are associated with a response time of 200 [ms]. These values are stored in advance in the storage unit 160 described above. In response to user operation on the operation unit 170 for selecting a response time according to, for example, the speed, reflectance, state, or the like of the workpiece WK, the setting management unit 151 reads, from the storage unit 160, a reference period, a spread width, and the number of addition operations corresponding to the selected response time and sets the read values as setting values.

The distance calculation unit 152 is configured to calculate the distance between the workpiece WK and the sensor 100 based on the plurality of received detection signals DS2. The distance calculation unit 152 uses, for example, the cumulative signal stored in the signal storage unit 147 as the plurality of received detection signals DS2. Specifically, the distance calculation unit 152 calculates a time difference between the detection signal DS1 when transmitted using the reference period and the cumulative signal which are the plurality of received detection signals DS2, by using, for example, the phase difference between the detection signal DS1 and the cumulative signal, and converts the time difference into the distance to the workpiece WK. As described above, the detection signal DS1 is transmitted at a variable signal period and is not transmitted at the reference period. However, the signal periods are spread with respect to the reference period in a range with a width that is twice the spread width, and thus the average of a sufficient number of periods of the detection signal DS1 can be regarded as being identical or substantially identical to the reference period.

The detection unit 153 is configured to detect the workpiece WK as the target based on the plurality of received detection signals.

As described above, in the sensor 100, a scramble value is calculated by a hash function, based on a value of a periodic pseudorandom number sequence and a unique value of the sensor 100, a variable signal period is set based on the scramble value, a detection signal is transmitted to the workpiece WK and the detection signal reflected by the workpiece WK is received, based on the signal period, the workpiece WK is detected based on a plurality of the received detection signals. This makes it possible to reduce the risk that, when a plurality of sensors are arranged, the signal periods of adjacent sensors coincide with each other. Therefore, unlike the related art, the user does not need to set different periods for the plurality of sensors, and it is possible to easily suppress a malfunction due to mutual interference. In addition, even when, in adjacent sensors, the signal periods are set using the values of the same pseudorandom number sequence, using the hash function to calculate the scramble value makes it possible to obtain scramble values as a number sequence obtained by changing the order (arrangement) of the periodic pseudorandom number sequence. Therefore, the risk that the signal periods set in the sensors are continuously synchronized with each other can be reduced, and the malfunction due to mutual interference can be further suppressed.

More specifically, the detection unit 153 is configured to detect the workpiece WK based on the generated cumulative signal. For example, the detection unit 153 compares, with the threshold value, the distance to the workpiece WK calculated based on the cumulative signal, and determines that the workpiece WK is present when the calculated distance is equal to or less than the threshold value, and determines that the workpiece WK is not present when the calculated distance is greater than the threshold value. The detection unit 153 outputs a signal corresponding to the determination result to the display unit 180 to display whether the workpiece WK is detected. The detection unit 153 outputs a signal corresponding to the determination result to the outside via, for example, the cable 101 illustrated in FIG. 1.

Detecting the workpiece WK based on the generated cumulative signal, as described above, makes it possible to average the detection signals received a plurality of times, and thus even if accidental phase coincidence between the signal periods of adjacent sensors occurs, the influence thereof can be weakened by the averaging.

Here, the difference between the case of using a varying signal period and the case of using a fixed signal period will be described. As illustrated on the right side of FIG. 8, in a case where a variable signal period based on scramble values is set, as in the sensor 100 of the present embodiment, and for example, there is noise that is phase synchronizing with the first signal period, the influence of the noise can be weakened. This is because the phases of the second, third, and fourth signal periods are shifted with respect to the phase of the first signal period, and thus, in the cumulative signal generated based on the detection signals for the four signal periods, the noise components are averaged. As a result, a peak appears at a time (distance) corresponding to the detection signals reflected by the workpiece WK. Note that, although the example in which the number of addition operations is four is illustrated for the sake of simplicity of description, the number of addition operations is preferably several hundred or more in practice.

In contrast, in a case where a fixed signal period is set, as illustrated on the left side of FIG. 8 for comparison with the sensor 100 of the present embodiment, and for example, there is noise that is phase synchronizing with the first signal period, the noise component is amplified. This is because the phases of the second, third, and fourth signal periods are the same as the phase of the first signal period, and thus, in the cumulative signal generated based on the detection signals for the four signal periods, the noise component is amplified. Therefore, a peak appearing at a time (distance) corresponding to the detection signals reflected by the workpiece WK may not be distinguished from the noise component, resulting in failing to detect the workpiece WK.

At least one of the setting management unit 151, the distance calculation unit 152, and the detection unit 153 may be implemented by the processor of the control unit 150 executing a program stored in the storage unit 160. When a program is executed, the program may be stored in a storage medium. The storage medium storing the program may be a non-transitory computer readable medium. The non-transitory storage medium is not particularly limited, but may be a storage medium such as a USB flash drive, an MMC, an SD memory card, or as SSD.

The functions of the control unit 150 illustrated in FIG. 2 are examples. The control unit 150 may have another function different from these functions, or may not have one or more of these functions.

### Processing Procedure

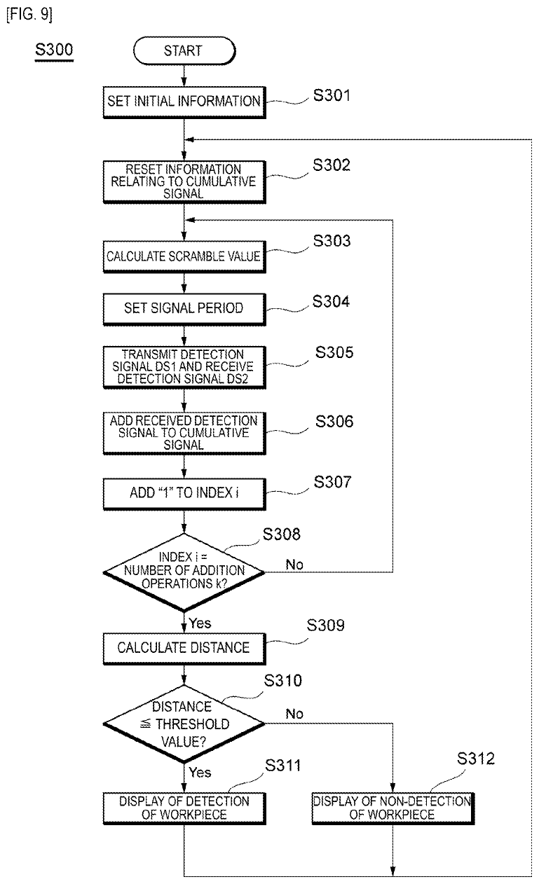

Next, a processing procedure performed by the sensor according to one embodiment will be described with reference to FIG. 9. FIG. 9 is a flowchart for explaining an example of presence detection processing S300 performed by the sensor 100 according to one embodiment.

The presence detection processing S300 is a process performed when the sensor 100 detects whether the workpiece WK is present. As illustrated in FIG. 9, first, the setting management unit 151 reads information related to the detection setting from the storage unit 160 and sets initial information (S301). The initial information is, for example, a seed value, an individual serial number, a spread width, a reference period, the number of addition operations k, a threshold value, and the like.

Next, the cumulative signal generation unit 146 resets the information related to the cumulative signal, to an initial state (S302). For example, the cumulative signal generation unit 146 sets an index i to “0”. The index i is an index indicating the number of addition operations of the received detection signals. The cumulative signal generation unit 146 sets the cumulative signal stored in the signal storage unit 147, to an initial value, for example, “0”, “Null”, or the like.

Next, the scramble value calculation unit 143 calculates a scramble value based on a value of the pseudorandom number sequence and a unique value of the sensor 100 (S303). The value of the pseudorandom number sequence is a value generated by the pseudorandom number generation unit 141 based on the seed value set in step S301. The unique value of the sensor 100 is the individual serial number itself set in step S301 or a hash value generated by the hash value generation unit 142 based on the individual serial number.

Next, the signal period setting unit 144 sets the signal period, based on the scramble value calculated in step S303 (S304). The signal period setting unit 144 calculates a variable signal period, based on the scramble value calculated in step S303 and the spread width and the reference period set in step S301. Based on the calculated signal note, the timing control unit 145 generates a timing signal and outputs the timing signal to the transmitting unit 120 and the cumulative signal generation unit 146.

Next, the transmitting and receiving unit 110 transmits the detection signal DS1 to the workpiece WK and receives the detection signal DS2 reflected by the workpiece WK, based on the signal period (S305).

Next, in response to input of a detection signal from the transmitting and receiving unit 110, the cumulative signal generation unit 146 reads the cumulative signal stored in the signal storage unit 147, and adds the received detection signal to the read cumulative signal (S306). The cumulative signal generation unit 146 writes, to the signal storage unit 147, the cumulative signal obtained by adding the detection signal. As a result, the cumulative signal stored in the signal storage unit 147 is updated.

Next, the cumulative signal generation unit 146 adds “1” to the index i (S307). As a result, the number of addition operations, which is the number of times a detection signal is added, is incremented.

Next, the cumulative signal generation unit 146 determines whether the index i is equal to the number of addition operations k (S308).

As a result of the determination in step S308, if the index i is not equal to the number of addition operations k, the processing returns to step S303. Then, steps S303 to S308 are repeated until the index i becomes equal to the number of addition operations k.

As a result of the determination of step S308, if the index i is equal to the number of addition operations k, the distance calculation unit 152 calculates the distance between the workpiece WK and the sensor 100 based on the plurality of detection signals (S309). Here, if the index i is equal to the number of addition operations k, the cumulative signal stored in the signal storage unit 147 is the result of addition operations of detection signals performed k times. Therefore, the distance calculation unit 152 can read the cumulative signal from the signal storage unit 147 and use the cumulative signal to calculate the distance between the workpiece WK and the sensor 100 based on the plurality of detection signals.

Next, the detection unit 153 determines whether the distance calculated in step S309 is equal to or less than the threshold value moderated in step S301 (S310).

As a result of the determination of step S310, if the calculated distance is equal to or less than the threshold value, it is considered that the detection signals reflected by the workpiece WK illustrated in FIG. 1, which may be present at a predetermined distance from the sensor 100, are received a plurality of times. Therefore, the detection unit 153 generates detection information indicating that the workpiece WK has been detected, and outputs the detection information to the display unit 180 to cause the display unit 180 to display the information that the workpiece WK has been detected (S311). The generated detection information is output to the outside via the cable 101 or the like illustrated in FIG. 1.

On the other hand, as a result of the determination of step S310, if the calculated distance is not equal to or less than the threshold value, that is, if the calculated distance is greater than the threshold value, it is considered that the detection signals reflected by an object other than the workpiece WK illustrated in FIG. 1, for example, the conveying device BC, the wall, and the like in the background of the workpiece WK, are received a plurality of times. In this case, the detection unit 153 generates non-detection information indicating that the workpiece WK is not detected, and outputs the non-detection information to the display unit 180 to cause the display unit 180 to display the information that the workpiece WK is not detected (S312). The generated non-detection information is output to the outside via the cable 101 or the like illustrated in FIG. 1.

After step S311 or step S312, steps S302 to S312 are repeated until a predetermined condition, such as power off, a setting change, or an operation mode change, is satisfied.

Note that, in the sequence and the flowchart described in the present embodiment, the order may be changed unless a contradiction occurs in the processing.

The sensor 100 of the present embodiment is not limited to a sensor using light as a signal medium, as described above. The sensor 100 of the present embodiment can use a signal medium other than light.

### Modified Example

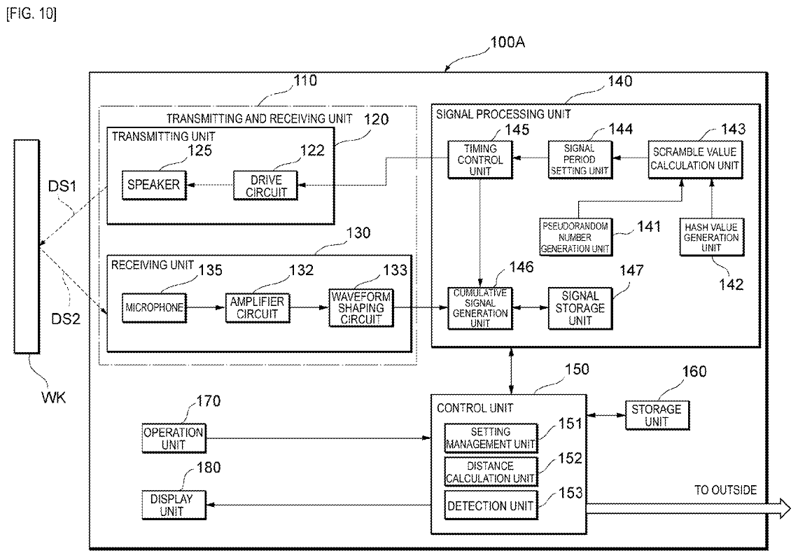

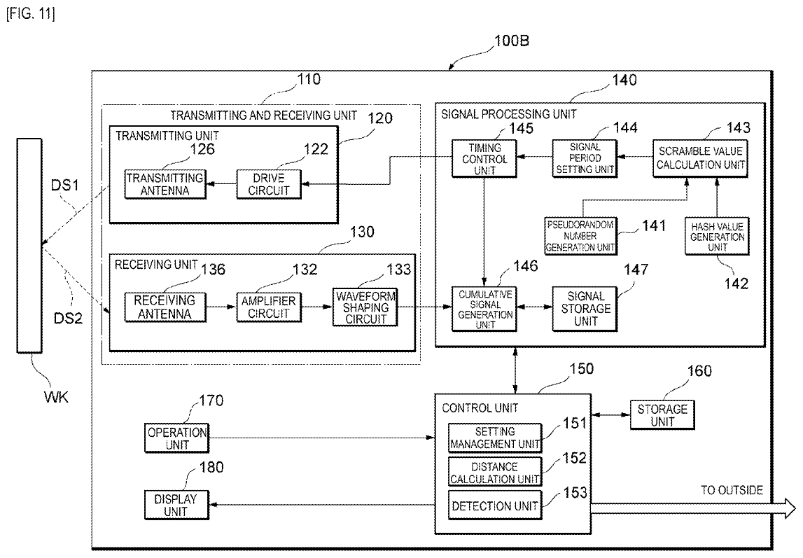

Next, modified examples of the sensor according to one embodiment will be described with reference to FIGS. 10 and 11. FIG. 10 is a configuration diagram illustrating a configuration of a sensor 100A according to a first modified example of one embodiment. FIG. 11 is a configuration diagram illustrating a configuration of a sensor 100B according to a second modified example of one embodiment. Note that, in the following description, components that are the same as or similar to those of the sensor 100 illustrated in FIG. 2 are denoted by the same or similar reference signs, and the description thereof will be omitted as appropriate. In addition, the same operations and effects by the same components will not be separately mentioned.

As illustrated in FIG. 10, the sensor 100A of the first modified example uses a sound wave signal as the detection signals DS1, DS2 instead of a light signal. Specifically, the transmitting unit 120 of the sensor 100A includes a speaker 125 instead of the light emitting element 121 illustrated in FIG. 2. The sound wave used by the sensor 100A are, for example, an ultrasonic wave. The speaker 125 is oriented toward the workpiece WK and is configured to emit the detection signal DS1, which is an ultrasonic signal, in response to input of an electric signal. The receiving unit 130 of the sensor 100A includes a microphone 135 instead of the light receiving element 131 illustrated in FIG. 2. The microphone 135 is oriented toward the workpiece WK, and is configured to convert the detection signal DS2, which is the sound wave signal reflected by the workpiece WK, into an electrical signal, in response to input of the detection signal DS2.

As illustrated in FIG. 11, the sensor 100B of the second modified example uses an electromagnetic wave signal as the detection signals DS1, DS2 instead of a light signal. Specifically, the transmitting unit 120 of the sensor 100B includes a transmitting antenna 126 instead of the light emitting element 121 illustrated in FIG. 2. The electromagnetic wave used by the sensor 100B is an electromagnetic wave called a millimeter wave that has a frequency in a range from about 30 GHz to about several hundred GHz, for example. The transmitting antenna 126 is a directional antenna having directivity, and is configured to emit the detection signal DS1, which is an electromagnetic wave signal, toward the workpiece WK. The receiving unit 130 of the sensor 100B includes a receiving antenna 136 instead of the light receiving element 131 illustrated in FIG. 2. The receiving antenna 136 is a directional antenna having directivity, and is configured to receive the detection signal DS2 which is the electromagnetic wave signal reflected by the workpiece WK.

As described above, the detection signals DS1, DS2 are any one of a light signal, a sound wave signal, and an electromagnetic wave signal, and thus the transmitting and receiving unit 110 for transmitting and receiving the detection signals DS1, DS2 can be easily implemented (realized).

The example embodiment of the present disclosure has been described above. According to the sensor 100, 100A, 100B according to one embodiment of the present disclosure, a scramble value is calculated by a hash function, based on a value of a periodic pseudorandom number sequence and a unique value of the sensor 100, 100A, 1000B, a variable signal period is set based on the scramble value, a detection signal is transmitted to the workpiece WK and the detection signal reflected by the workpiece WK is received, based on the signal period, the workpiece WK is detected based on a plurality of the received detection signals. This makes it possible to reduce the risk that, when a plurality of sensors are arranged, the signal periods of adjacent sensors coincide with each other. Therefore, unlike the related art, the user does not need to set different periods for the plurality of sensors, and it is possible to easily suppress a malfunction due to mutual interference. In addition, even when, in adjacent sensors, the signal periods are set using the values of the same pseudorandom number sequence, using the hash function to calculate the scramble value makes it possible to obtain scramble values as a number sequence obtained by changing the order (arrangement) of the periodic pseudorandom number sequence. Therefore, the risk that the signal periods set in the sensors are continuously synchronized with each other can be reduced, and the malfunction due to mutual interference can be further suppressed.

According to the detection method according to one embodiment of the present disclosure, a scramble value is calculated by a hash function, based on a value of a periodic pseudorandom number sequence and a unique value of the sensor 100, 100A, 1000B, a variable signal period is set based on the scramble value, a detection signal is transmitted to the workpiece WK and the detection signal reflected by the workpiece WK is received, based on the signal period, the workpiece WK is detected based on a plurality of the received detection signals. This makes it possible to reduce the risk that, when a plurality of sensors are arranged, the signal periods of adjacent sensors coincide with each other. Therefore, unlike the related art, the user does not need to set different periods for the plurality of sensors, and it is possible to easily suppress a malfunction due to mutual interference. In addition, even when, in adjacent sensors, the signal periods are set using the values of the same pseudorandom number sequence, using the hash function to calculate the scramble value makes it possible to obtain scramble values as a number sequence obtained by changing the order (arrangement) of the periodic pseudorandom number sequence. Therefore, the risk that the signal periods set in the sensors are continuously synchronized with each other can be reduced, and the malfunction due to mutual interference can be further suppressed.

Note that the above-described embodiment is provided for facilitating understanding of the present disclosure, and is not intended to limit the interpretation of the present disclosure. The present disclosure may be modified/improved without departing from the gist thereof, and the present disclosure also includes equivalents thereof. In other words, such variations that are obtained by those skilled in the art appropriately making a design change to the embodiment are also included in the scope of the present disclosure as long as the variations include the features of the present disclosure. For example, each element included in the embodiment as well as the arrangement, material, condition, shape, size, and the like of each element are not limited to those exemplified and may be changed appropriately. The embodiment is merely illustrative, and it goes without saying that partial replacements or combinations of configurations illustrated in different embodiments are allowed, and these are also included in the scope of the present disclosure as long as these include the features of the present disclosure.

### Supplementary Note 1

A sensor 100 including,
a calculation unit 143 configured to calculate a scramble value by a hash function, based on a value of a pseudorandom number sequence and a unique value of the sensor 100, the pseudorandom number sequence being a periodic number sequence,
a setting unit 144 configured to set a signal period based on the scramble value, the signal period being variable,
a transmitting and receiving unit 110 configured to transmit a detection signal DS1 to a target WK and receive the detection signal DS2 reflected by the target WK, based on the signal period, and
a detection unit 153 configured to detect the target WK based on a plurality of the received detection signals DS2.

### Supplementary Note 11

A detection method for a sensor 100, the detection method including,
calculating a scramble value by a hash function, based on a value of a pseudorandom number sequence and a unique value of the sensor 100, the pseudorandom number sequence being a periodic number sequence,
setting a signal period, based on the scramble value, the signal period being variable,
transmitting a detection signal DS1 to a target WK and receiving the detection signal DS2 reflected by the target WK, based on the signal period, and
detecting the target WK, based on a plurality of the received detection signals DS2.

### REFERENCE SIGNS LIST

100, 100-1, 100-2, 100-3, 100A, 100B . . . Sensor, 101, 101-1, 101-2, 101-3 . . . Cable, 102-1, 102-2, 102-3 . . . Control Target Device, 110 . . . Transmitting And Receiving Unit, 120 . . . Transmitting Unit, 121 . . . Light Emitting Element, 122 . . . Drive Circuit, 125 . . . Speaker, 126 . . . Transmitting Antenna, 130 . . . Receiving Unit, 131 . . . Light Receiving Element, 132 . . . Amplifier Circuit, 133 . . . Waveform Shaping Circuit, 135 . . . Microphone, 136 . . . Receiving Antenna, 140 . . . Signal Processing Unit, 141 . . . Pseudorandom Number Generation Unit, 142 . . . Hash Value Generation Unit, 143 . . . Scramble Value Calculation Unit, 144 . . . Signal Period Setting Unit, 145 . . . Timing Control Unit, 146 . . . Cumulative Signal Generation Unit, 147 . . . Signal Storage Unit, 150 . . . Control Unit, 151 . . . Setting Management Unit, 152 . . . Distance Calculation Unit, 153 . . . Detection Unit, 160 . . . Storage Unit, 170 . . . Operation Unit, 180 . . . Display Unit, 200 . . . Detection System, BC . . . Conveying Device, S300 . . . Presence Detection Processing, WK . . . Workpiece.

1. A sensor comprising:
a calculation unit configured to calculate a scramble value by a hash function, based on a value of a pseudorandom number sequence and a unique value of the sensor, the pseudorandom number sequence being a periodic number sequence;
a setting unit configured to set a signal period, based on the scramble value, the signal period being variable;
a transmitting and receiving unit configured to transmit a detection signal to a target and receive the detection signal reflected by the target, based on the signal period; and
a detection unit configured to detect the target based on a plurality of the detection signals received.

2. The sensor according to claim 1, wherein:
the setting unit calculates the signal period based on a reference period, a spread width, and the scramble value.

3. The sensor according to claim 1, further comprising:
a pseudorandom number generation unit configured to generate a value of the pseudorandom number sequence, based on a predetermined seed value.

4. The sensor according to claim 1, further comprising:
a hash value generation unit configured to generate a hash value, based on the unique value of the sensor,
wherein the calculation unit calculates the scramble value based on the value of the pseudorandom number sequence and the hash value.

5. The sensor according to claim 4, wherein:
the number of digits of the hash value is equal to the number of digits of the value of the pseudorandom number sequence, and
the scramble value is calculated by using an exclusive OR operation of the value of the pseudorandom number sequence and the hash value.

6. The sensor according to claim 1, further comprising:
a cumulative signal generation unit configured to generate a cumulative signal, based on the plurality of detection signals received,
wherein the detection unit detects the target, based on the cumulative signal.

7. The sensor according to claim 6, further comprising:
a storage unit configured to store the cumulative signal,
wherein in response to reception of the detection signal, the cumulative signal generation unit adds the detection signal to the cumulative signal stored in the storage unit to update the cumulative signal.

8. The sensor according to claim 1, wherein:
the transmitting and receiving unit includes a transmitting unit configured to transmit the detection signal to the target, based on the signal period, and a receiving unit configured to receive the detection signal reflected by the target, based on the signal period.

9. The sensor according to claim 1, further comprising:
an input unit configured to receive input of information.

10. The sensor according to claim 1, wherein:
the detection signal is any one of a light signal, a sound wave signal, and an electromagnetic wave signal.

11. A detection method for a sensor, the detection method comprising:
calculating a scramble value by a hash function, based on a value of a pseudorandom number sequence and a unique value of the sensor, the pseudorandom number sequence being a periodic number sequence;
setting a signal period, based on the scramble value, the signal period being variable;
transmitting a detection signal to a target and receiving the detection signal reflected by the target, based on the signal period; and
detecting the target based on a plurality of the detection signals received.

12. The sensor according to claim 2, wherein:
the detection signal is any one of a light signal, a sound wave signal, and an electromagnetic wave signal.

13. The sensor according to claim 3, wherein:
the detection signal is any one of a light signal, a sound wave signal, and an electromagnetic wave signal.

14. The sensor according to claim 4, wherein:
the detection signal is any one of a light signal, a sound wave signal, and an electromagnetic wave signal.

15. The sensor according to claim 5, wherein:
the detection signal is any one of a light signal, a sound wave signal, and an electromagnetic wave signal.

16. The sensor according to claim 6, wherein:
the detection signal is any one of a light signal, a sound wave signal, and an electromagnetic wave signal.

17. The sensor according to claim 7, wherein:
the detection signal is any one of a light signal, a sound wave signal, and an electromagnetic wave signal.

18. The sensor according to claim 8, wherein:
the detection signal is any one of a light signal, a sound wave signal, and an electromagnetic wave signal.

19. The sensor according to claim 9, wherein:
the detection signal is any one of a light signal, a sound wave signal, and an electromagnetic wave signal.
